(19) United States
(12) Patent Application Publication
(10) Pub. No.: US 2012/0126288 A1
(43) Pub. Date: May 24, 2012

(54) Semiconductor device and method of manufacturing the same

(75) Inventor: Yasunori Bito, Kanagawa (JP)

(73) Assignee: Renesas Electronics Corporation, Kanagawa (JP)

(21) Appl. No.: 13/317,849

(22) Filed: Oct. 31, 2011

(30) Foreign Application Priority Data
Nov. 18, 2010 (JP) 2010-257950

(51) Int. Cl. H01L 27/06; H01L 21/28

(52) U.S. Cl. 257/192; 438/590; 257/E27.015; 257/E21.19

(57) ABSTRACT

A semiconductor device having first and second stacks formed successively over a common substrate, in which the first stack that remains after removing the second stack comprises a field effect transistor, the second stack that is stacked over the first stack comprises a device different from the field effect transistor, and the first stack comprising the field effect transistor has an etching stopper layer that defines a stopping position of a recess formed in the first stack and comprises InGaP, a lower compound semiconductor layer that is disposed below a gate electrode disposed in the recess and comprises AlGaAs, and a spacer layer that is interposed between the etching stopper layer and the lower compound semiconductor layer for preventing phosphorus contained in the etching stopper layer from thermally diffusing as far as the lower compound semiconductor layer and chemically bonding with constituents elements of the lower compound semiconductor layer.

### CROSS-REFERENCE TO RELATED APPLICATIONS

The disclosure of Japanese Patent Application No. 2010-257950 filed on Nov. 18, 2010 including the specification, drawings, and abstract is incorporated herein by reference in its entirety.

### BACKGROUND

The present invention concerns a semiconductor device and a method of manufacturing the semiconductor device.

A bipolar field effect transistor (BiFET) device having a hetero bipolar transistor {hereinafter sometimes referred to simply as a Heterojunction Bipolar Transistor (HBT)} and a field effect transistor (hereinafter sometimes referred to simply as FET) formed over one identical substrate has been known.

The BiFET device is manufactured by using an epitaxial wafer in which a semiconductor epitaxial layer where HBT is fabricated and a semiconductor epitaxial wafer where a FET is fabricated are formed over an identical compound semiconductor substrate (such as GaAs substrate). A recess for disposing the gate of the FET is formed by selective wet etching using an InGaP layer contained in the epitaxial wafer as an etching stopper layer. The method has an advantage that the etching stopping position can be controlled simply and a number of wafers can be processed at once compared with an existent method of using an AlGaAs layer as an etching stopper layer.

US Patent Laid-Open No. 2007/0278523 discloses a BiFET utilizing an InGaP layer as an etching stopper layer. As shown in FIG. 1 of US Patent laid-open No. 2007/0278523, a buffer layer, an n⁺-AlGaAs doping layer, an AlGaAs spacer layer, an undoped InGaAs channel layer, an AlGaAs spacer layer, n⁺-AlGaAs doping layer, an AlGaAs barrier layer, an InGaP etching stopper layer, an n⁺-GaAs ohmic contact layer, an InGaP etching stopper layer, an n⁺-GaAs sub-collector layer, an n⁻-GaAs collector layer, p⁺-GaAs base layer, n-InGaP emitter layer, n-GaAs emitter layer, and an n⁺-InGaAs emitter contact layer are successively formed over an epitaxial wafer above an semi-insulating GaAs substrate. Then, the BiFET device shown in FIG. 4 of US Patent laid-open No. 2007/0278523 is manufactured by way of the steps of etching, formation of electrodes, and formation of insulating films. The FET portion disclosed in the drawing uses a HEMT (High Electron Mobility Transistor) structure in which the undoped InGaAs layer functions as a high mobility channel layer.

Japanese Unexamined Patent Publication No. 2009-224407discloses a BiHFET device in which a bipolar transistor (HBT) and a hetero junction field effect transistor (HFET) are formed over an identical substrate. The device disclosed in Japanese Unexamined Patent Publication No. 2009-224407 has an InGaP etching stopper region 106. However, Japanese Unexamined Patent Publication No. 2009-224407 does not specifically disclose an etching stopper layer upon forming a recess in the HFET region.

Japanese Unexamined Patent Publication Nos. 2008-60397, 2007-157918, and 2002-184787 disclose a technique concerning single FETs. Proc. CS MANTECH Conf., pp. 281-284(2010) discloses that the channel electron mobility of a high electron mobility channel transistor (HEMT) is deteriorated in the epitaxial wafer for the BiFET. As a technique that has not yet been laid open but relates to the BiFET, Japanese Patent Application No. 2010-143647 was filed (Japanese Patent Application No. 2010-143647 is not prior art in view of the present application).

### SUMMARY

The present inventors found that the BiFET device involves a problem of having higher ON resistance compared with a single FET manufactured by the same etching process (that is, a device in which the HBT is not formed but only the FET is formed over the substrate). For investigating the reason that the ON resistance of FET included in the BiFET device is higher than the ON resistance of single FET, the present inventors have made evaluation/investigation as will be described below.

As the ON resistance value of FET in the BiFET device shown in FIG. 4 of US Patent laid-open No 2007/0278523, a value of 2.0 to 2.5 Ωmm was obtained. This is a value higher by 0.5 to 1.0 Ωmm than the ON resistance value of 1.5 Ωmm of FET manufactured from an epitaxial wafer in which only the FET epitaxial layer is formed over the GaAs substrate (hereinafter sometimes referred to simply as a single FET). It has been known by other companies in the relevant field, that the electron mobility in the channel of the high electron mobility channel transistor (HEMT) is deteriorated in the epitaxial wafer for the BiFET and this is also reported in Proc. CS MANTECH Conf., pp. 281-284 (2010). When the electron mobility in the FET channel layer of the BiFET epitaxial wafer shown in FIG. 4 of US Patent laid-open No. 2007/0278523 is evaluated, a value of 6400 cm²/V·sec is obtained which is a value substantially identical with 6500 cm²/V·sec for the electron mobility in the channel of FET in which only the FET epitaxial structure is grown over the GaAs substrate. Accordingly, it can not be assumed that deterioration of the electron mobility in the channel layer may increase the ON resistance.

Then, by using a device shown in FIG. 26, the sheet resistance of the FET channel layer and the access resistance between the n⁺-GaAs cap layer and the InGaAs channel layer were evaluated respectively according to a TLM method based on a Transmission Line Model. References 311 to 319 shown in FIG. 26 correspond to the compound semiconductor layers 111 to 119 disclosed in FIG. 1 of US Patent laid-open No. 2007/027523. Reference 320 shown in FIG. 26 denotes an ohmic electrode.

According to the evaluation, a result that the access resistance =0.7 to 1.0 Ωmm for the FET portion in the BiFET device was obtained. The access resistance in a case of growing only the FET epitaxial structure over the GaAs substrate is 0.4 Ωmm. The access resistance of the FET portion in the BiFET device is higher by as much as 0.3 to 0.6 Ωmm than the access resistance of the single FET. Considering that the ON resistance of FET is given substantially as: (channel sheet resistance component)+(access resistance)×2, it may be roughly explained that the amount of the deterioration of 0.5 to 1.0 Ωmm for the ON resistance corresponds to increment in the access resistance.

It has been confirmed that the contact resistance between the ohmic electrode and the n⁺-GaAs cap layer is identical between the FET portion in the BiFET device and the single FET based on the result of measurement according to the TLM method conducted by another measuring pattern.

In view of the evaluation described above, it has been found that the ON resistance of FET in the BiFET device is high because of high access resistance in the semiconductor from the n⁺-GaAs cap layer to the InGaAs channel layer just below the FET ohmic electrode.

The reason why the phenomenon described above occurs inherently to the BiFET epitaxial wafer but does not occur in the single FET epitaxial wafer can be explained as below. The example shown in FIG. 4 of US Patent Laid-Open No. 2007/0278523 has a structure in which a HBT epitaxial layer having a total thickness as large as 0.5 μm or more is grown over a FET epitaxial layer. For epitaxially growing such a thick semiconductor layer, the FET epitaxial layer is exposed to a high temperature of about 600° C. to 650° C. for a long time. It has been found that AlGaAsP is formed at an interface between an InGaP etching stopper layer and an AlGaAs barrier layer in the FET portion. This is considered to be attributable to that P diffuses toward AlGaAs during epitaxial growing of the HBT because of strong bonding force between Al and P. AlGaAsP of large band gap forms a potential barrier on the side of the conduction band. It is considered that the access resistance between the n⁺-GaAs cap layer and the InGaAs channel layer increases as a result.

As apparent from the explanation described above, it has been strongly demanded to suppress the deterioration of the ON resistance of FET contained in the BiFET device. The evaluation/investigation described above was performed independently by the present inventors for investigating the reason why the ON resistance of FET contained in the BiFET device is higher than the ON resistance of single FET. Accordingly, the explanation described above does not mean or self admit the prior art at all.

A semiconductor device according to an aspect of the present invention has first and second stacks formed successively over a common substrate, in which
the first stack that remains after removing the second stack includes a field effect transistor, the second stack that is stacked over the first stack comprises a device different from the field effect transistor described above, and
the first stack including the field effect transistor contains an etching stopper layer that defines a stopping position for a recess formed in the first stack and includes InGaP,
a lower compound semiconductor layer that is disposed below a gate electrode disposed in the recess and includes AlGaAs, and
a spacer layer interposed between the etching stopper layer and the lower compound semiconductor layer and preventing phosphorus (P) contained in the etching stopper layer from thermally diffusing as far as the lower compound semiconductor layer and chemically bonding with constituent elements of the lower compound semiconductor layer. The spacer layer can prevent the phosphorus from thermally diffusing and prevent the ON resistance of field effect transistors from deteriorating.

A method of manufacturing the semiconductor device according to another aspect of the present invention includes:
forming, over a substrate, a first stack (the first stack containing an etching stopper layer that defines the stopping position for a recess and comprises InGaP, a lower compound semiconductor layer disposed below a gate electrode disposed in the recess and comprising AlGaAs, and a spacer layer interposed between the etching stopper layer and the lower compound semiconductor layer, and suppressing phosphorus (P) contained in the etching stopper layer from diffusing thermally as far as the lower compound semiconductor layer and chemically bonding with constituent elements of the lower compound semiconductor layer);
epitaxially growing a second stack over the first stack;
partially removing the second stack to expose the upper surface of the first stack;
forming a recess to the upper surface of the first stack till it reaches the stopping position in accordance with the etching stopper layer; and
forming a gate electrode in the recess.

According to the aspects of the invention, deterioration of the ON resistance of FET contained in a BiFET device can be suppressed.

### BRIEF DESCRIPTION OF THE DRAWINGS

FIG. 1 is a cross sectional view showing an outlined cross sectional configuration of a BiFET device according to a first embodiment;

FIG. 2 is a schematic manufacturing step view of a BiFET device according to the first embodiment;

FIG. 3 is a schematic manufacturing step view of a BiFET device according to the first embodiment;

FIG. 4 is a schematic manufacturing step view of a BiFET device according to the first embodiment;

FIG. 5 is a schematic manufacturing step view of a BiFET device according to the first embodiment;

FIG. 6 is a schematic manufacturing step view of a BiFET device according to the first embodiment;

FIG. 7 is a schematic manufacturing step view of a BiFET device according to the first embodiment;

FIG. 8 is a schematic manufacturing step view of a BiFET device according to the first embodiment;

FIG. 9 is a schematic manufacturing step view of a BiFET device according to the first embodiment;

FIG. 10 is a cross sectional view showing a schematic cross sectional configuration of a BiFET device according to a second embodiment;

FIG. 11 is a cross sectional view showing a schematic cross sectional configuration of a BiFET device according to a third embodiment;

FIG. 12 is a cross sectional view showing a schematic cross sectional configuration of a BiFET device according to a fourth embodiment;

FIG. 13 is a cross sectional view showing a schematic cross sectional configuration of a BiFET device according to a fifth embodiment;

FIG. 14 is a cross sectional view showing a schematic cross sectional configuration of a BiFET device according to a sixth embodiment;

FIG. 15 is a cross sectional view showing a schematic cross sectional configuration of a BiFET device according to a seventh embodiment;

FIG. 16 is a cross sectional view showing a schematic cross sectional configuration of a BiFET device according to an eighth embodiment;

FIG. 17 is a cross sectional view showing a schematic cross sectional configuration of a BiFET device according to a ninth embodiment;

FIG. 18 is a cross sectional view showing a schematic cross sectional configuration of a BiFET device according to a tenth embodiment;

FIG. 19 is a cross sectional view showing a schematic cross sectional configuration of a BiFET device according to an eleventh embodiment;

FIG. 20 is a cross sectional view showing a schematic cross sectional configuration of a BiFET device according to a twelfth embodiment;

FIG. 21 is a cross sectional view showing a schematic cross sectional configuration of a BiFET device according to a thirteenth embodiment;

FIG. 22 is a cross sectional view showing a schematic configuration of a semiconductor integrated circuit according to a fourteenth embodiment;

FIG. 23 is a schematic circuit diagram of a semiconductor integrated circuit according to the fourteenth embodiment;

FIG. 24 is a schematic circuit diagram of a semiconductor integrated circuit according to a fifteenth embodiment;

FIGS. 25A and 25B are a cross sectional view showing a schematic cross sectional configuration of an FET device according to a reference example; and

FIG. 26 is an explanatory view showing a method of evaluating access resistance.

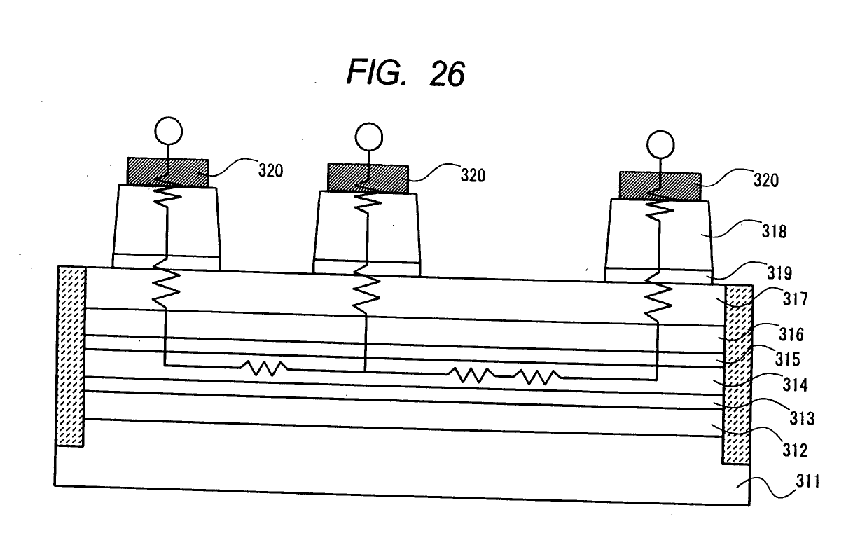

### DETAILED DESCRIPTION

Preferred embodiments of the present invention are to be described below. Each of the embodiments to be described later can be combined appropriately and synergistic effects due the combination can also be asserted. Identical elements carry the same reference numerals for which duplicate explanation is to be omitted. For the sake of convenience of explanation, drawings are simplified.

### First Embodiment

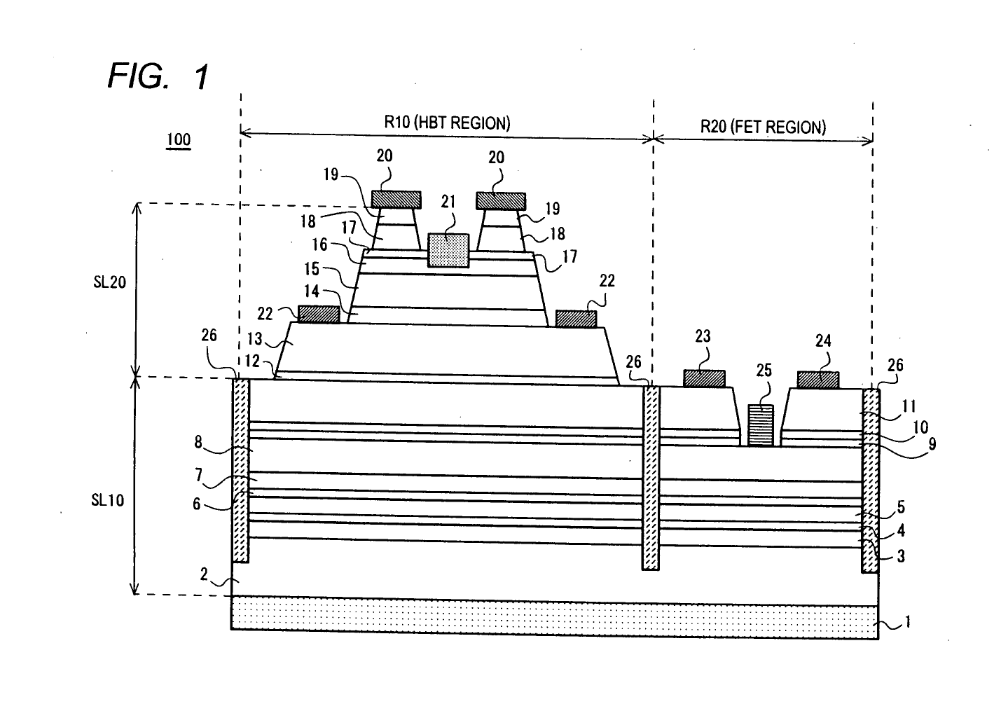

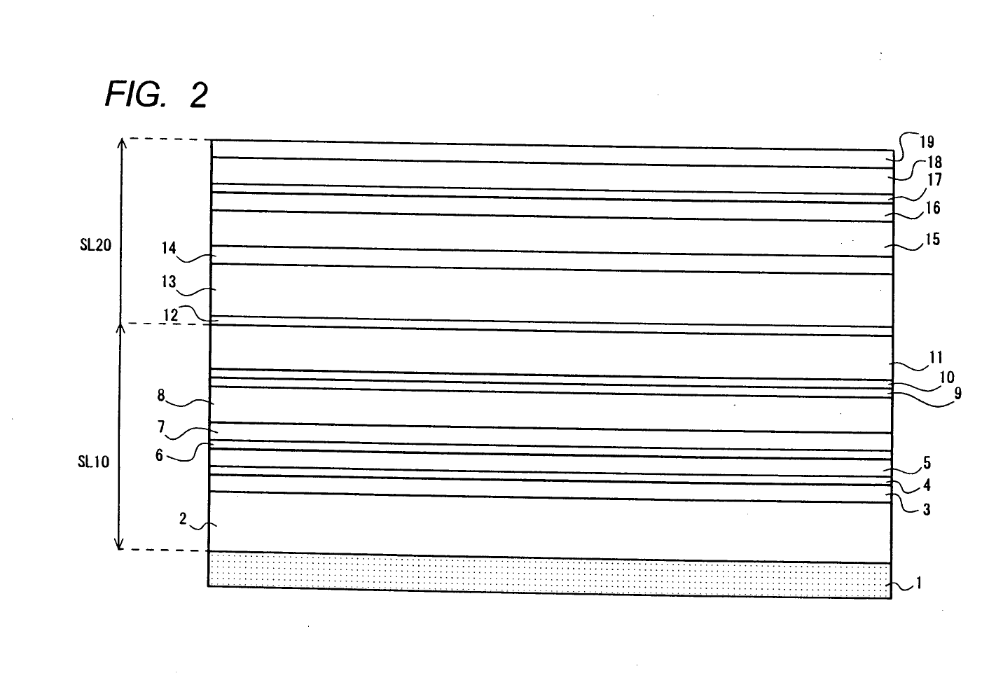

A first embodiment of the invention is to be described with reference to FIG. 1 to FIG. 9. FIG. 1 is a cross sectional view showing a schematic cross sectional configuration of a BiFET device. FIG. 2 to FIG. 9 are schematic manufacturing step views of the BiFET device.

In this embodiment, as will be apparent from the description below during manufacture of a BiFET epitaxial wafer, a spacer layer 9 comprising GaAs is interposed between an etching stopper layer 10 comprising InGaP and a barrier layer 8 comprising AlGaAs to suppress phosphorus (P) contained in the etching stopper layer 10 from thermally diffusing as far as the barrier layer 8 and chemically bonding with the constituent elements of the barrier layer 8. Increase in the access resistance can be prevented by suppressing phosphorus (P) contained in the etching stopper layer 10 from diffusing into the AlGaAs layer and forming AlGaAsP. Specific materials for the spacer layer are not restricted only to GaAs so long as they do not contain Al. Further, etching may be either wet or dry etching.

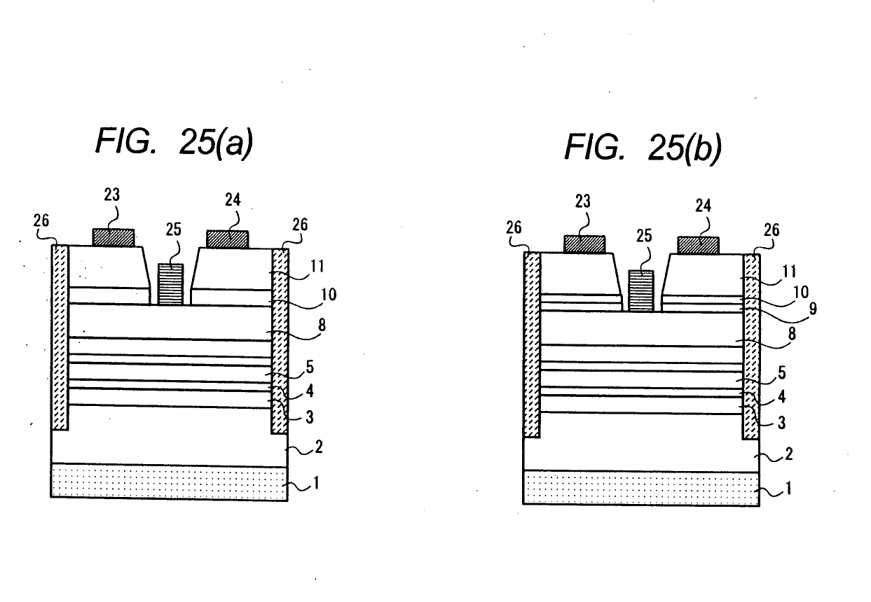

As apparent from the reference example shown in FIGS. 25A and 25B, the effect of interposing the spacer layer 9 described above is obtained in a case of the BiFET device but is not obtained in a case of a single FET device in which a bipolar transistor is not incorporated.

Description is to be made specifically. As shown in FIG. 1, a BiFET device 100 comprises a first stack SL10 and a second stack SL20 stacked successively over a common substrate 1. A bipolar transistor (HBT) is formed in a first region (HBT region) R10 and a field effect transistor (FET) is formed in a second region (FET region) R20 of the BiFET device 100. In the second region R20, the second stack SL20 is removed, the first stack SL10 remains, and the FET is fabricated in this state.

As shown in FIG. 1, the BiFET device 100 has, over a common substrate 1, a buffer layer 2, an electron supply layer 3, a spacer layer 4, a channel layer 5, a spacer layer 6, an electron supply layer 7, a barrier layer 8, a spacer layer 9, an etching stopper layer 10, an ohmic contact layer (sometimes also referred to as a cap layer) 11, an etching stopper layer 12, a sub-collector layer 13, a collector layer (also serving as an etching stopper layer) 14, a collector layer 15, a base layer 16, an emitter layer 17, an emitter layer 18, and an emitter contact layer 19. Further, the BiFET device 100 has an emitter electrode 20, a base electrode 21, a collector electrode 22, a source electrode 23, a drain electrode 24, a gate electrode 25, and an insulating region 26.

The first stack SL10 comprises compound semiconductor layers 2 to 11 stacked over the common substrate 1. The second stack SL20 comprises compound semiconductor layers 12 to 19 stacked over the first stack SL10.

The buffer layer 2 is a compound semiconductor layer of 500 nm thickness. The electron supply layer 3 is an n⁺-AlGaAs layer of 4 nm thickness with doping of Si impurity at 3×10¹⁸ cm⁻². The spacer layer 4 is an undoped AlGaAs layer of 2 nm thickness. The channel layer 5 is an undoped InGaAs layer of 15 nm thickness. The spacer layer 6 is an undoped AlGaAs layer of 2 nm thickness. The electron supply layer 7 is an n⁺-AlGaAs layer of 10 nm thickness with doping of Si impurity at 3×10¹⁸ cm⁻². The barrier layer 8 is an undoped AlGaAs layer of 25 nm thickness. The spacer layer 9 is an undoped GaAs layer of 2 nm thickness. The etching stopper layer 10 is an undoped InGaP layer of 10 nm thickness. The ohmic contact layer 11 is an n⁺-GaAs layer of 150 nm thickness with doping of Si impurity at 4×10¹⁸ cm⁻³. The etching stopper layer 12 is an n⁺-InGaP layer of 20 nm thickness with doping of Si impurity at 4×10¹⁸ cm⁻³. The sub-collector layer 13 is an n⁺-GaAs layer of 850 nm thickness with doping of Si impurity at 4×10¹⁸ cm⁻³. The collector layer 14 is an n-InGaP layer of 60 nm thickness with doping of Si impurity at 1×10¹⁶ cm⁻³. The collector layer 15 is an n⁻-GaAs layer of 900 nm thickness with doping of Si impurity at 5×10¹⁵ cm⁻³. The base layer 16 is a p⁺-GaAs layer of 90 nm thickness with doping of C impurity at 4×10¹⁹ cm⁻³. The emitter layer 17 is an n-InGaP layer of 30 nm thickness with doping of Si impurity at 4×10¹⁷ cm⁻³. The emitter layer 18 is an n-GaAs layer of 100 nm thickness with doping of Si impurity at 3×10¹⁷ cm⁻³. The emitter contact layer 19 is an n⁺-InGaAS layer of 100 nm thickness with doping of Se impurity at 2×10¹⁹ cm⁻³. The electrodes 20 to 25 are formed of metals such as Al. Device isolation between HBT and FET is ensured by the insulating region 26.

In the BiFET device 100, since the bipolar transistor and the field effect transistor are formed over a common substrate, the functional circuit can be made monolithic. For example, an amplifier circuit can be comprised of a bipolar transistor and a switching device can be comprised of a field effect transistor. Specific operation mechanisms of the HBT and the FET incorporated in the BiFET device 100 have been known generally to persons skilled in the art. Accordingly, in the present application, detailed description for their operation is to be omitted. The mode of using HBT (for example, emitter grounding, base grounding, or collector grounding) is optional.

Manufacturing steps of the BiFET device 100 shown in FIG. 1 is to be described with reference to FIG. 2 to FIG. 9.

At first, as shown in FIG. 2, a first stack SL10 and a second stack SL20 are formed successively by epitaxial growing over a common substrate 1. In the process of epitaxially growing the second stack SL20 over the first stack SL10, the first stack SL10 is exposed to a high temperature of about 600° C. to 650° C. for a long time. In this case, there is a possibility that phosphorus (P) contained in the etching stopper layer 10 as a constituent layer of the first stack SL10 may thermally diffuse to the barrier layer 8.

In this embodiment, a GaAs spacer layer 9 is interposed between the InGaP etching stopper layer 10 and the AlGaAs barrier layer 8. Thus, in the process of epitaxially growing the second stack SL20 over the first stack SL10, even when the first stack SL10 is exposed to a high temperature of about 600° C. to 650° C. for a long time, the spacer layer can effectively prevent phosphorus (P) contained in the InGaP etching stopper layer 10 from diffusing as far as the AlGaAs barrier layer 8 and chemically bonding with constituent elements of the AlGaAs barrier layer 8.

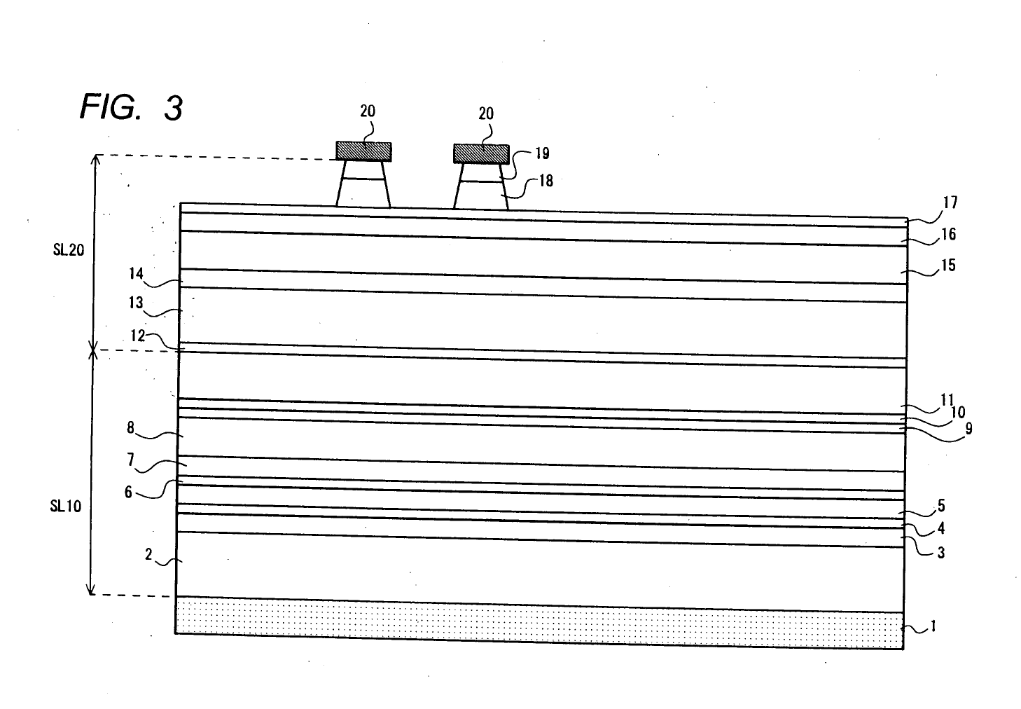

Then, as shown in FIG. 3, emitter electrodes 20 are formed and then the emitter contact layer 19 and the emitter layer 18 are partially removed by etching. Specifically, after forming a WSi layer at first over the entire surface of the epitaxial wafer shown in FIG. 2, it is patterned by using a photoresist. Then, the WSi layer is etched by using a photoresist pattern as a mask. Thus, the remaining portion of the WSi layer forms the emitter electrodes 20. Then, the n⁺-InGaAs emitter contact layer 19 and the n-GaAs emitter layer 18 are etched and removed partially by using the emitter electrode 20 as a mask. The etching is performed till the surface of the n-InGaP emitter layer 17 is exposed. Thus, a structure shown in FIG. 3 is obtained.

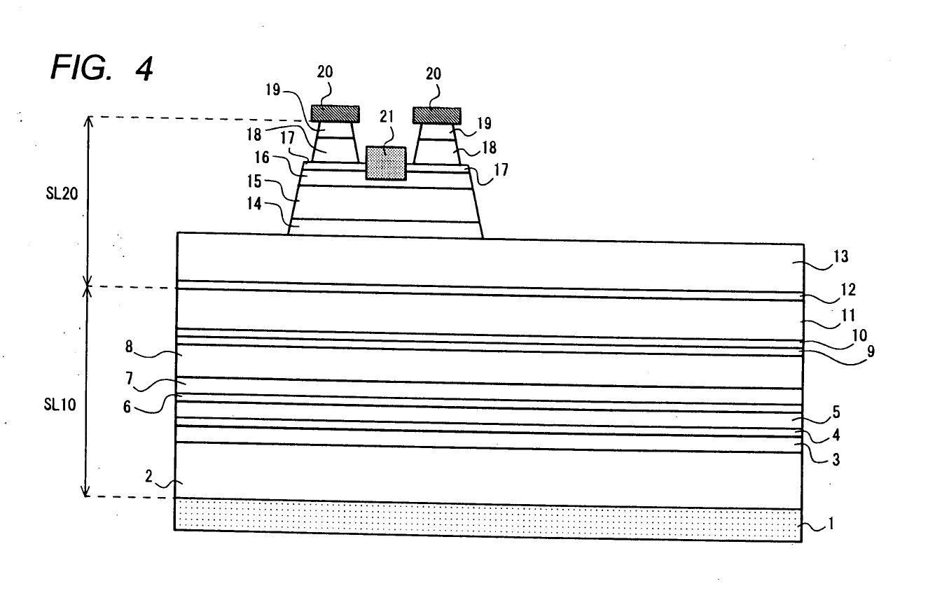

Then, as shown in FIG. 4, a base electrode 21 is formed, and the emitter layer 17—the collector layer 14 are partially removed by etching. Specifically, a Pt-Ti-Pt-Au layer is formed over the n-InGaP emitter layer 17 by a vapor deposition lift-off method using a photoresist as a mask. The Pt-Ti-Pt-Au layer is put into contact with the p⁺-GaAs base layer 16 by a heat treatment to form a base electrode 21. Subsequently, the n-InGaP emitter layer 17, the p⁺-GaAs base layer 16, the n-GaAs collector layer 15, and the n⁺-InGaP collector layer 14 are removed partially by etching using a photoresist as a mask. The etching is performed till the n⁺-GaAs sub-collector layer 13 is exposed. Thus, a structure shown in FIG. 4 is obtained.

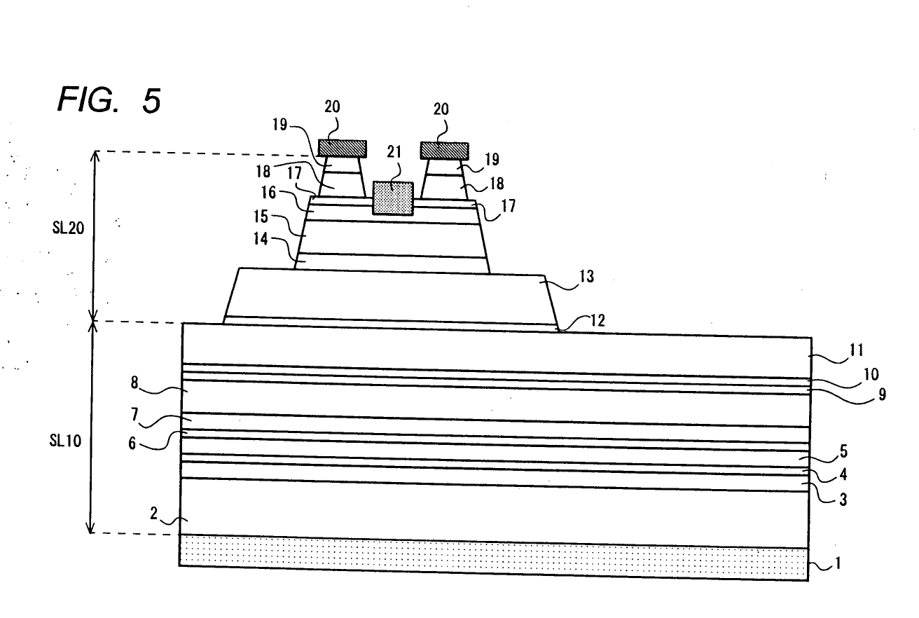

Then, as shown in FIG. 5, an etching treatment is performed. Specifically, the n⁺-GaAs sub-collector layer 13 and the n⁺-InGaP etching stopper layer 12 are partially removed by etching using a photoresist as a mask. The etching treatment is performed till the n⁺-GaAs cap layer 11 is exposed. Thus, a structure shown in FIG. 5 is obtained.

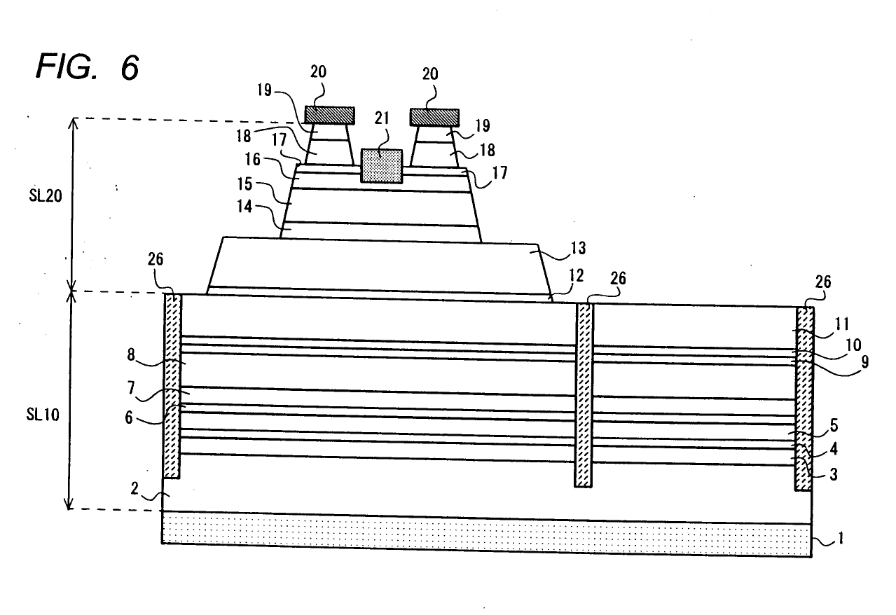

Then, as shown in FIG. 6, insulating regions are formed. Specifically boron ions are implanted using a photoresist as a mask to form insulating regions 26. Thus, a structure shown in FIG. 6 is obtained.

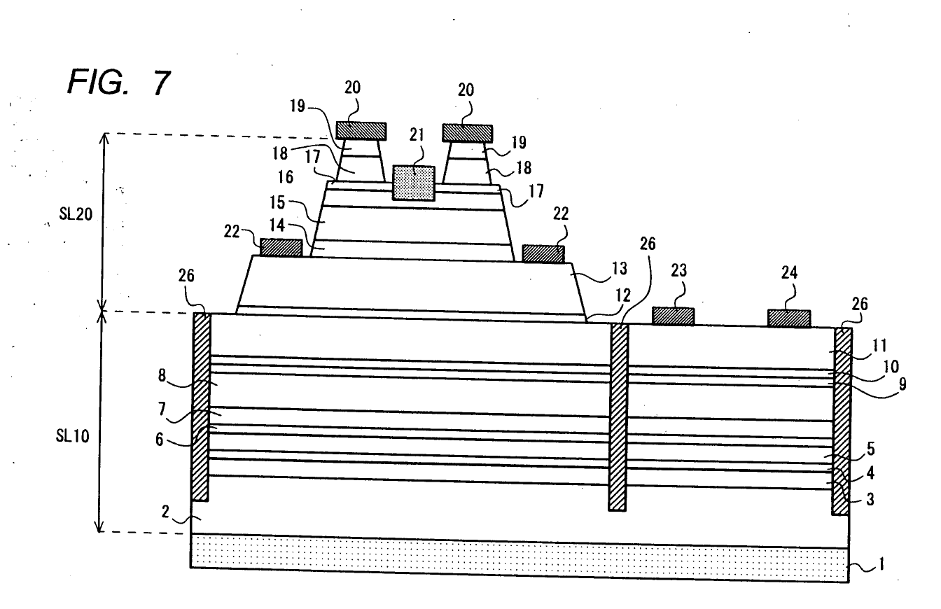

Then, as shown in FIG. 7, electrodes are formed. Specifically, an AuGe-Ni-Au layer is formed over the n⁺-GaAs sub-collector layer 13 by a vapor deposition lift off method using a photoresist as a mask to form collector electrodes 22. In the same manner, an AuGe-Ni-Au layer is formed over the n⁺-GaAs cap layer 11 by a vapor deposition lift off method using a photoresist as a mask to form a source electrode 23 and a drain electrode 24. Then, the electrodes are put into ohmic contact with the compound semiconductor layer in which the electrodes are disposed by a heat treatment. Thus a structure shown in FIG. 7 is obtained.

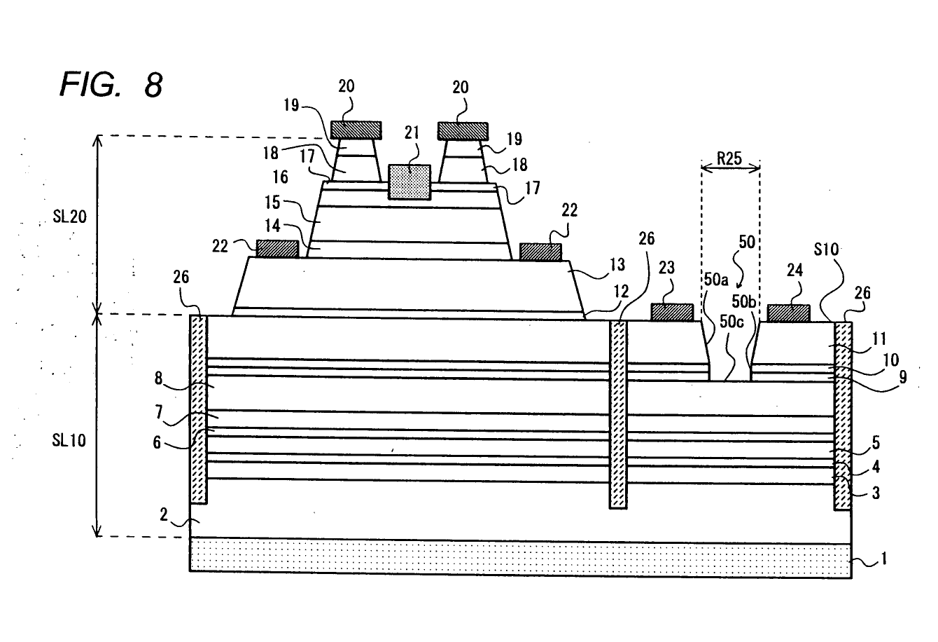

Then, as shown in FIG. 8, a stack surface S10 is selectively etched to form a recess 50 between the electrodes 23 and 24. Specifically, a gate-open-patterned photoresist film is formed in a region R25 where a gate structure is to be disposed. The n⁺-GaAs cap layer 11 is removed by etching by a mixed etchant comprising sulfuric acid, aqueous hydrogen peroxide, and water using the photoresist layer as a mask. Successively, the n-InGaP etching stopper layer 10 is removed by etching by a mixed etchant comprising hydrochloric acid and water. The undoped GaAs spacer layer 9 below the etching stopper layer 10 is formed to a thickness as thin as 2 nm. Accordingly, the spacer layer 9 is removed at the same time with removal of the etching stopper layer 10 by etching. The surface of the undoped AlGaAs barrier layer 8 is exposed by the etching treatment to obtain a structure shown in FIG. 8.

As shown in FIG. 8, the recess 50 has a lateral side 50a, a lateral side 50b, and a bottom 50c. The recess 50 has a tapered portion enlarging upward. That is, the recess 50 has a portion where the bore diameter is enlarged from bottom up. The lateral side 50a has a portion extending so as to approach the electrode 24 in the downward direction. The lateral side 50b has a portion extending so as to approach the electrode 23 in the downward direction.

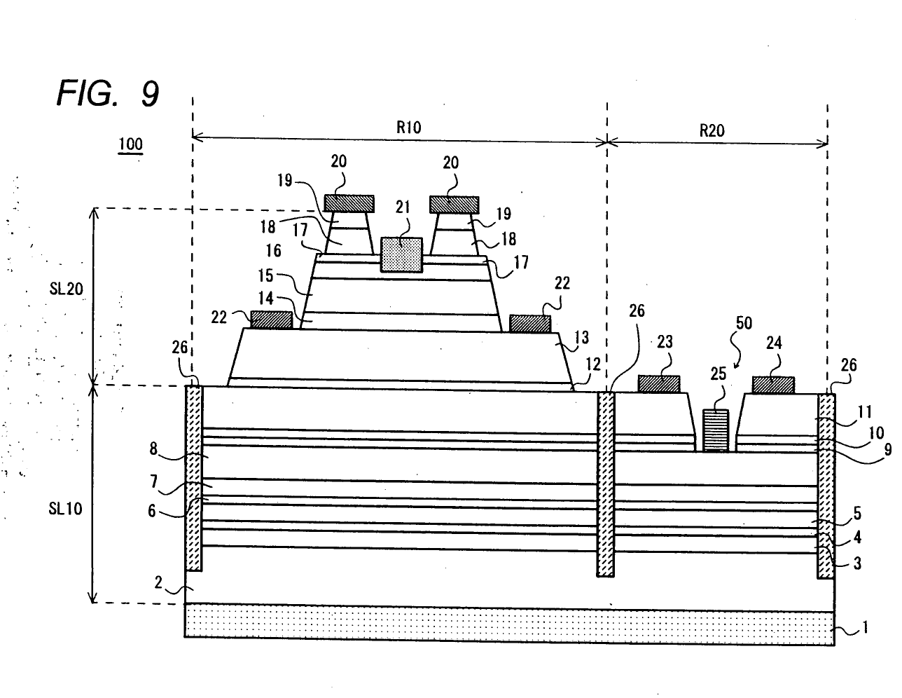

Then, as shown in FIG. 9, a gate electrode 25 is fabricated in the recess 50. Specifically, the gate electrode 25 is formed by a vapor deposition lift off method using a mask identical with the mask upon forming the recess. Thus, a BiFET device 100 shown in FIG. 9 is obtained.

In this embodiment, as apparent from the explanation described above, the GaAs spacer layer 9 interposed between the AlGaAs barrier layer 8 and the InGaP etching stopper layer 10 suppresses diffusion of P from the InGaP etching stopper layer 10 to the AlGaAs barrier layer 8 during epitaxial wafer growing of BiFET. As a result, since AlGaAsP that generates a potential barrier on the side of the conduction band is not formed, also the access resistance is not increased. While the n⁺-GaAs cap layer 11 is disposed over the InGaP etching stopper layer 10, increase in the access resistance due to diffusion of P does not occur also at the interface on this side. As a result, an ON resistance of 1.3 Ωmm which is about identical with that in the case where only the FET epitaxial layer (corresponding to stack SL10) is grown over the substrate can be obtained.

It may suffice that the thickness of the spacer layer 9 to be interposed is more than the thickness capable of suppressing the diffusion of phosphorus (P). The thickness of the spacer layer 9 is preferably 0.5 nm or more and, more preferably, 2 nm or more.

A spacer layer 9 as thin as 2 nm is used in the explanation described above. In this case, also the GaAs spacer layer 9 can be removed by etching upon removing the InGaP etching stopper layer 10. As a result, the gate electrode 25 can be in contact with the AlGaAs barrier layer 8 having a high Schottky barrier and a FET having a high gate forward voltage and also a high gate breakdown voltage can be manufactured.

### Second Embodiment

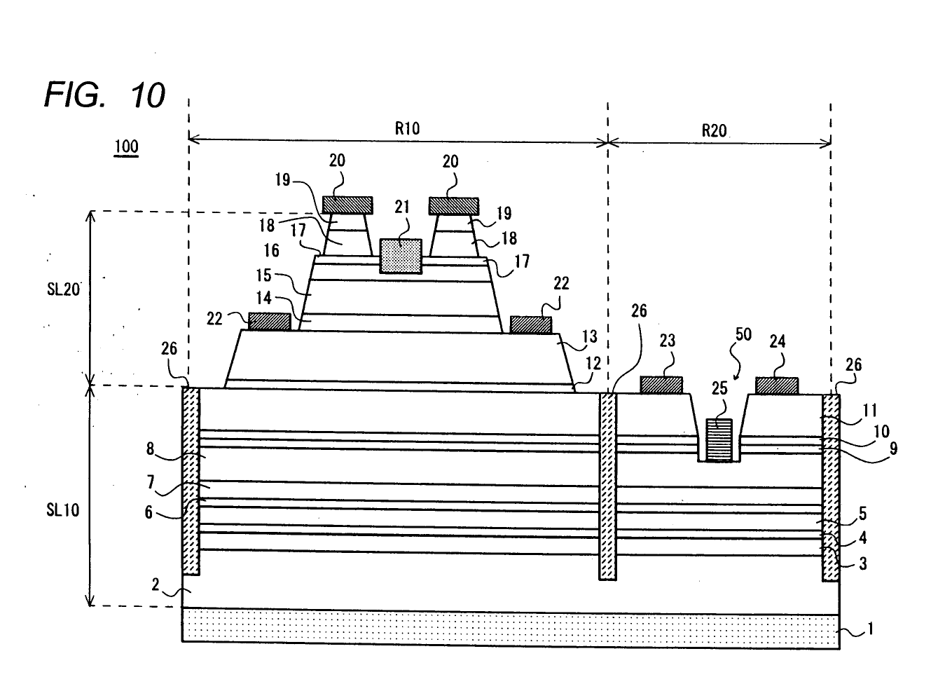

A second embodiment is to be described with reference to FIG. 10. FIG. 10 is a cross sectional view showing a schematic cross sectional configuration of a BiFET device. In this embodiment, different from the first embodiment, the time for etching an InGaP etching stopper layer 10 is made longer and an AlGaAs barrier layer 8 is etched by about several nm from the surface thereof. Also in this embodiment, the same effect as that in the first embodiment (low FET ON resistance and high gate breakdown voltage) can be obtained.

### Third Embodiment

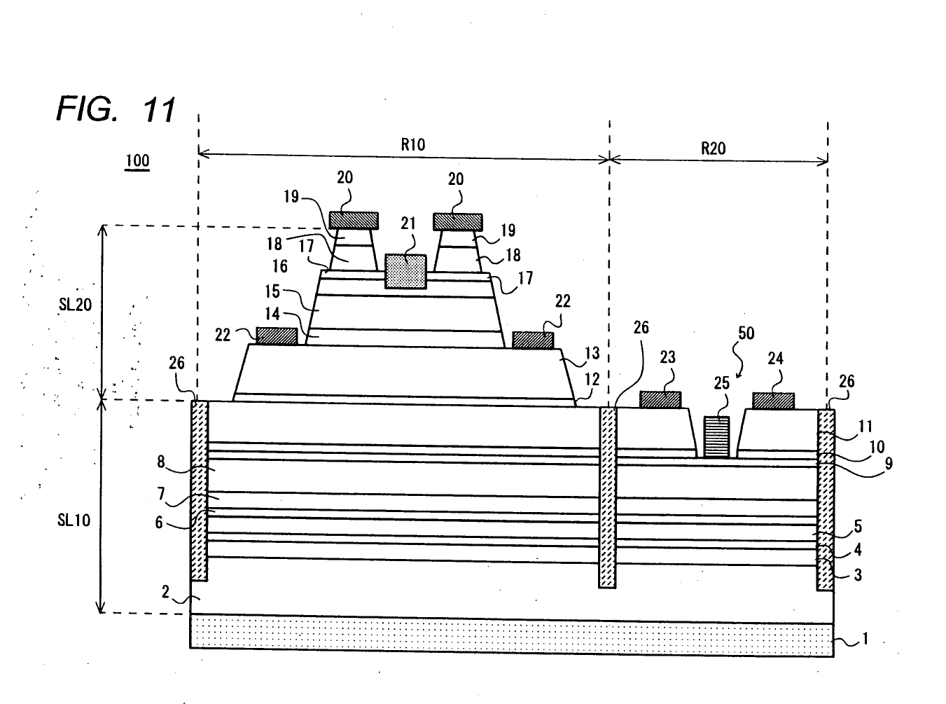

A third embodiment is to be described with reference to FIG. 11. FIG. 11 is a cross sectional view showing a schematic cross sectional configuration of a BiFET device. In this embodiment different from the first embodiment, a GaAs spacer layer 9 is left by making the time for etching the InGaP etching stopper layer 10 shorter. Also in this embodiment, the same effect as that in the first embodiment can be obtained.

In this embodiment, the distance between the surface of the semiconductor and the channel layer on the side of the gate is increased, and the effect of a surface depletion layer extending from the surfaces is mitigated to increase the sheet carrier concentration in the channel layer on the side of the gate. As a result, the sheet resistance on the side of the gate decreases to obtain a lower ON resistance of FET than that in the first embodiment. Since the thickness of the GaAs spacer layer 9 just below the gate is as thin as 2 nm, there is no problem of deteriorating of the gate breakdown voltage.

When the thickness of the spacer layer 9 is increased, a GaAs layer is present also just below the gate electrode of the FET. The GaAs layer has a lower Schottky barrier than the AlGaAs layer to lower the gate forward voltage and lower the gate breakdown voltage. In view of the above, a thin GaAs layer is used as the spacer layer 9 in this embodiment. In this case, no significant lowering of the breakdown voltage is generated due to the Schottky barrier of the AlGaAs layer just below the spacer layer 9. For suppressing the deterioration of the gate breakdown voltage, the thickness of the spacer layer 9 is preferably 10 nm or less.

### Fourth Embodiment

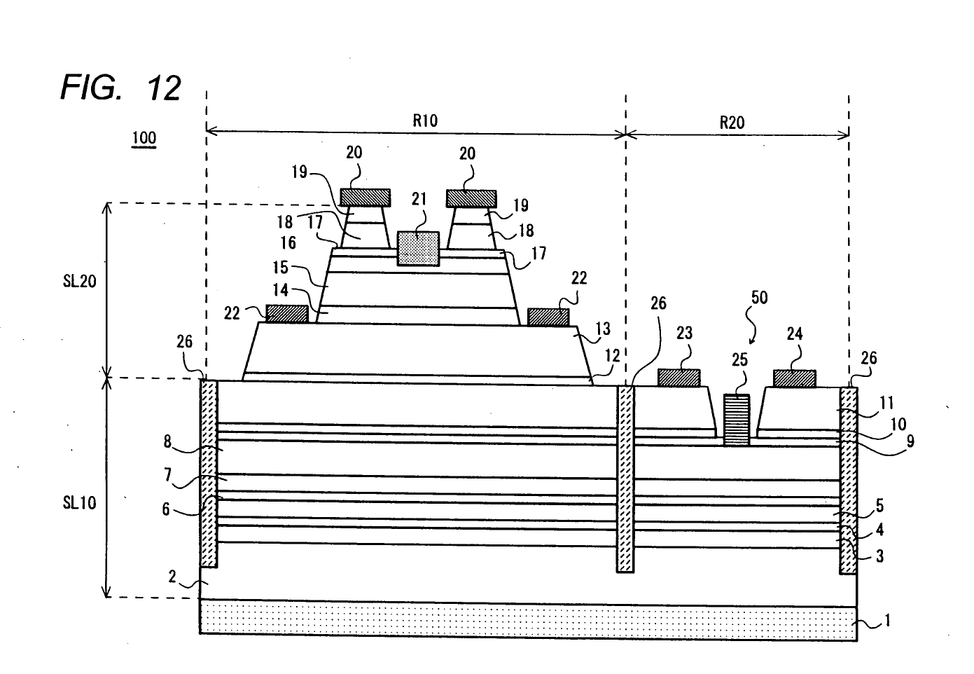

A fourth embodiment is to be described with reference to FIG. 12. FIG. 12 is a cross sectional view showing a schematic cross sectional configuration of a BiFET device. In this embodiment, different from the first embodiment, a GaAs spacer layer 9 is left on the side of a gate electrode 25 formed over an AlGaAs barrier layer 8. Also in this embodiment, the ON resistance of FET can also be lowered in the same manner as in the first embodiment and high gate breakdown voltage can be obtained in the same manner as in the first embodiment.

### Fifth Embodiment

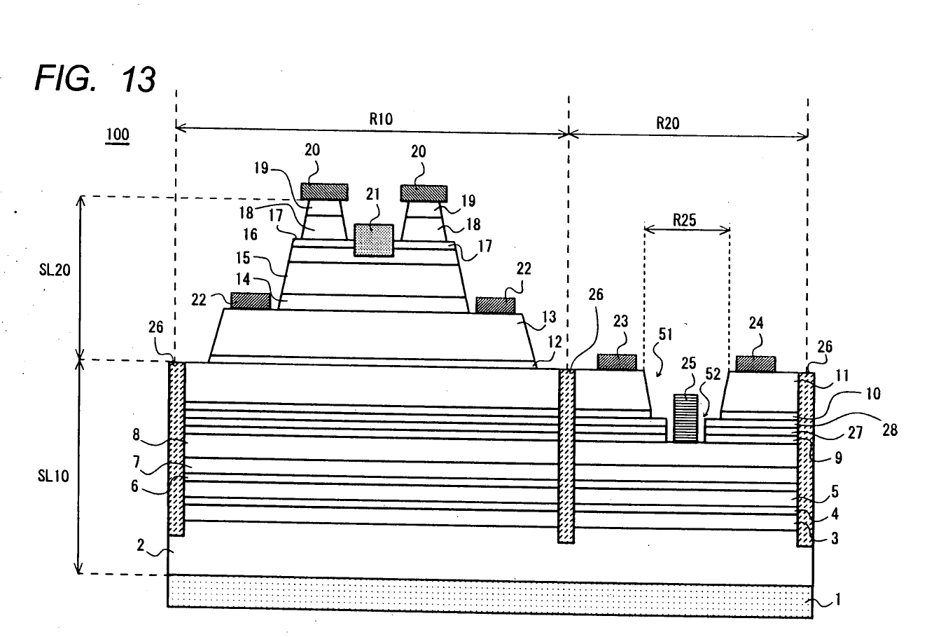

A fifth embodiment is to be described with reference to FIG. 13. FIG. 13 is a cross sectional view showing a schematic cross sectional configuration of a BiFET device. In this embodiment, different from the first embodiment, an InGaP etching stopper layer 27 and a GaAs layer 28 are interposed between a GaAs spacer layer 9 and an InGaP etching stopper layer 10. By stacking the etching stopper layer as a multilayer, a double recess structure having two-step gate recess can be formed. As schematically shown in FIG. 13, a recess 51 formed in a region R25 and, subsequently, a recess 52 is formed. The bore diameter of the recess 51 is larger than the bore diameter of the recess 52.

Also in this embodiment, since the GaAs spacer layer 9 is interposed so as to prevent P from diffusing from an InGaP etching stopper layer 27 to an AlGaAs barrier layer 8, low ON resistance of FET can be obtained in the same manner as in the first embodiment. Further, the double recessed structure can moderate an electric field at the gate end to obtain a higher gate breakdown voltage.

### Sixth Embodiment

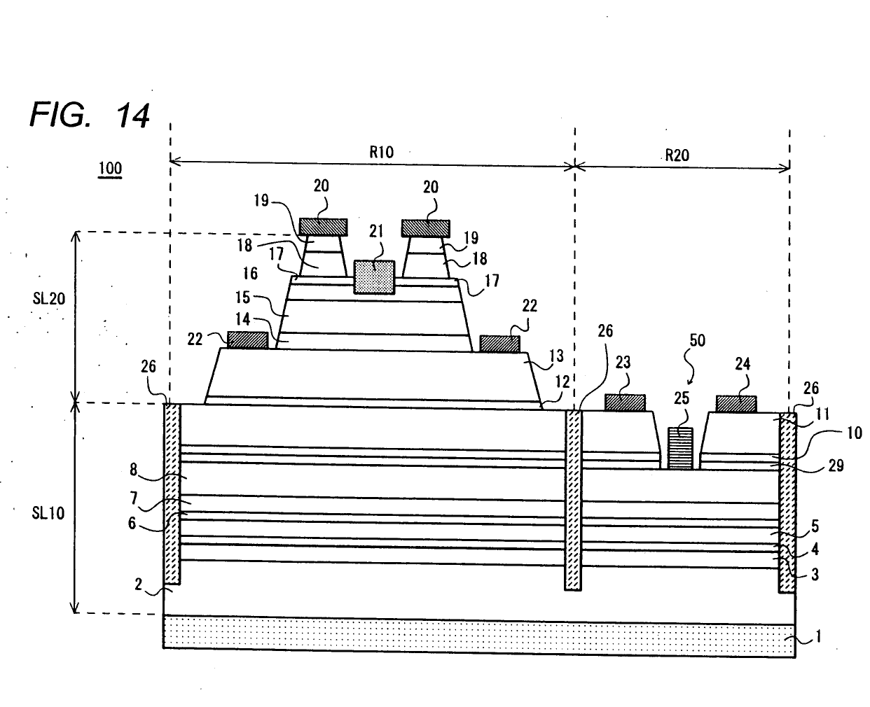

A sixth embodiment is to be described with reference to FIG. 14. FIG. 14 is a cross sectional view showing a schematic cross sectional configuration of a BiFET device. In this embodiment, an n-GaAs spacer layer 29 with doping of Si impurity at 5×10¹⁷ cm⁻³ is used instead of the undoped GaAs spacer layer 9 shown in the first embodiment. Also in this case, the same effect as that in the first embodiment can be obtained.

By doping to the GaAs spacer layer 29 as in this embodiment, the access resistance can be decreased further without lowering the gate breakdown voltage. As a result, the effect of decreasing the resistance due to doping is synergistically combined to the effect of the GaAs spacer layer to obtain lower ON resistance of FET and a gate breakdown voltage substantially identical with that in the first embodiment can be obtained. Further, in a case where gate breakdown voltage may be lowered with no problem, the amount of doping to the GaAs spacer layer 29 can be increased to about 4×10¹⁸ cm⁻³.

### Seventh Embodiment

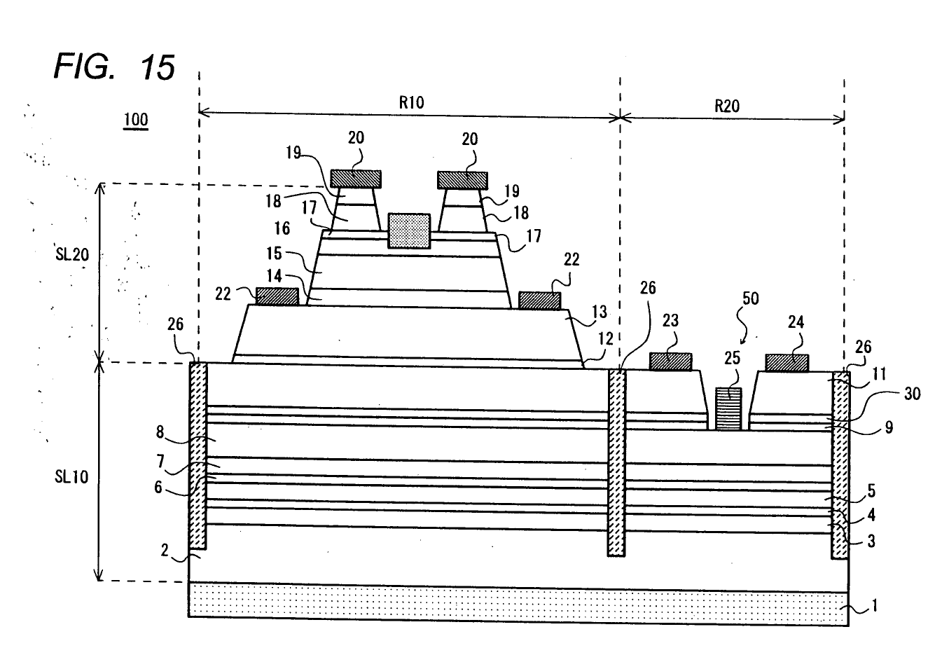

A seventh embodiment is to be described with reference to FIG. 15. FIG. 15 is a cross sectional view showing a schematic cross sectional configuration of BiFET device. In this embodiment, an n⁺-InGaP etching stopper layer 30 with doping of Si impurity at 4×10¹⁸ cm⁻³ is used instead of the undoped InGaP etching stopper layer 10 shown in the first embodiment. Also in this case, the same effect as that in the first embodiment can be obtained.

Doping to an InGaP etching stopper layer 30 as in this embodiment can further decrease the access resistance without lowering the gate breakdown voltage. As a result, the effect of decreasing the resistance due to doping is synergistically combined to the effect of the GaAs spacer layer 9 to obtain lower ON resistance of FET. Further, since the Si impurity can be doped to a higher concentration in InGaP than in GaAs, the amount of doping to the etching stopper layer 30 may be increased to about 1×10¹⁹ cm⁻³.

### Eighth Embodiment

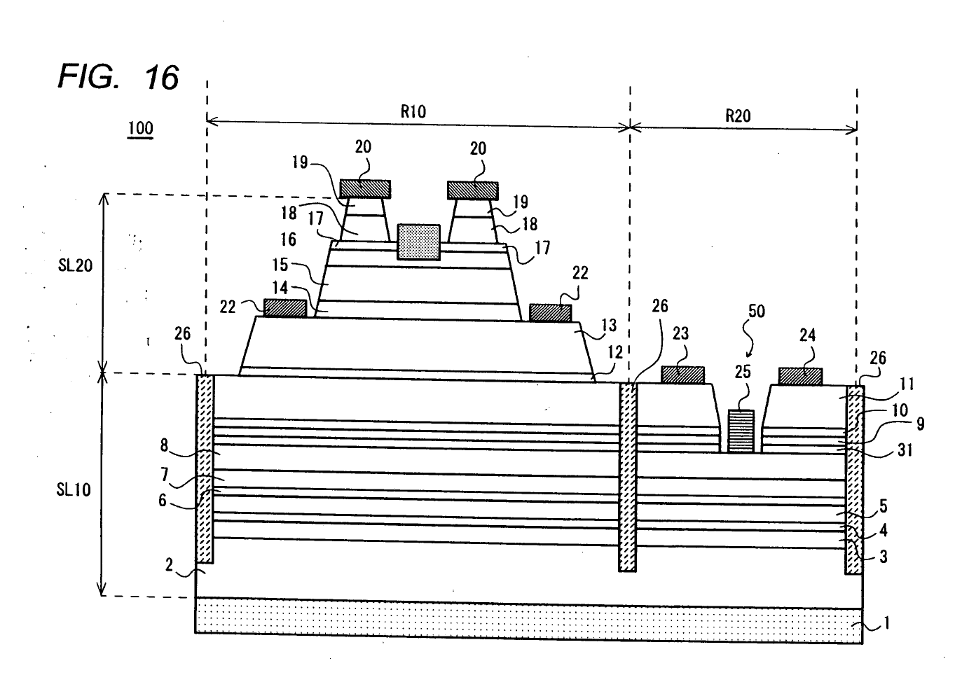

An eighth embodiment is to be described with reference to FIG. 16. FIG. 16 is a cross sectional view showing a schematic cross sectional configuration of BiFET device. In this embodiment, an impurity diffusion layer 31 is interposed between an undoped AlGaAs barrier layer 8 and a GaAs spacer layer 9 shown in the first embodiment. An impurity diffusion layer 31 is an n⁺-AlGaAs layer of 2 nm thickness with doping of Si impurity at 1×10¹⁸ cm⁻³. Also in this embodiment, the same effect as in the first embodiment can be obtained. In this embodiment, the n⁺-AlGaAs layer 31 is removed by making the time longer for removing an InGaP etching stopper layer 10 by etching. Then, a gate electrode 25 is disposed over the exposed undoped AlGaAs barrier layer 8.

As in this embodiment, interposing the n⁺-AlGaAs layer 31 and removing it by etching from the region for forming the gate electrode can further decrease the access resistance without lowering the gate breakdown voltage. As a result, the effect of decreasing the resistance due to doping is combined synergistically to the effect of the GaAs spacer layer 9 and lower ON resistance of FET can be obtained and substantially the same gate breakdown voltage as that in the first embodiment can be obtained.

### Ninth Embodiment

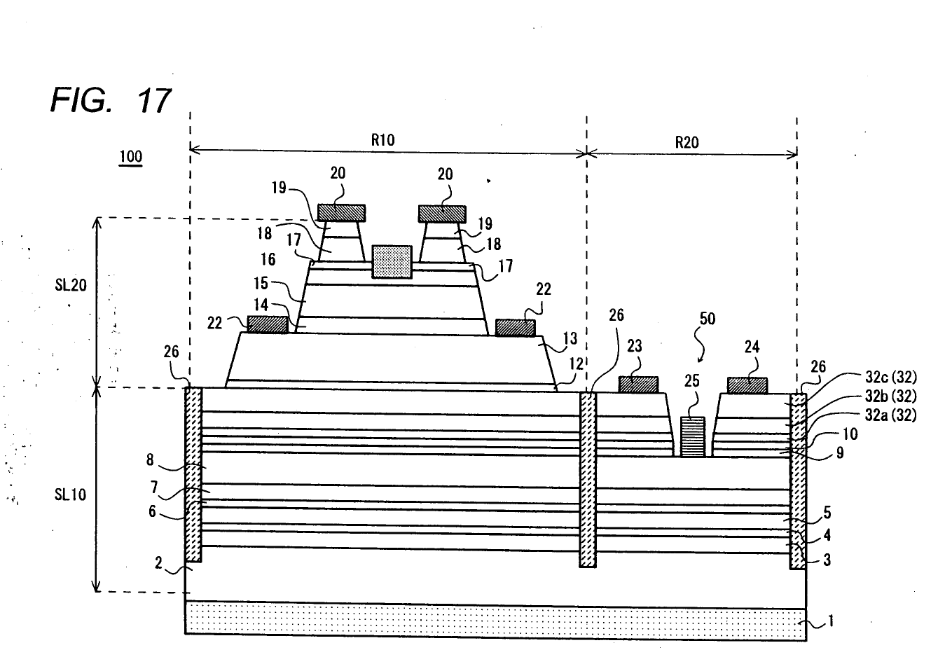

A ninth embodiment is to be described with reference to FIG. 17. FIG. 17 is a cross sectional view showing a schematic cross sectional configuration of a BiFET device. In this embodiment, a cap stack 32 including a low-doped intermediate layer is used instead of the n⁺-GaAs cap layer 11 shown in the first embodiment. Specifically, the cap stack 32 comprises, from the side of the substrate, an n⁺-GaAs layer 32a of 5 nm thickness with doping of Si impurity at 1×10¹⁸ cm⁻³, an n⁻-GaAs layer 32b of 50 nm thickness with doping of Si impurity at 4×10¹⁷ cm⁻³, and an n⁺-GaAs layer 32c of 100 nm thickness with doping of Si impurity at 4×10¹⁸ cm⁻³. Also in this embodiment, the same effect as that in the first embodiment can be obtained. In the first embodiment, the cap layer 11 is the n⁺-GaAs layer of 150 nm thickness with doping of Si impurity at 4×10¹⁸ cm⁻³.

As in this embodiment, by interposing the n⁻-GaAs layer 32b at high resistance, a high gate breakdown voltage can be obtained without using the double recessed structure shown in the fifth embodiment.

### Tenth Embodiment

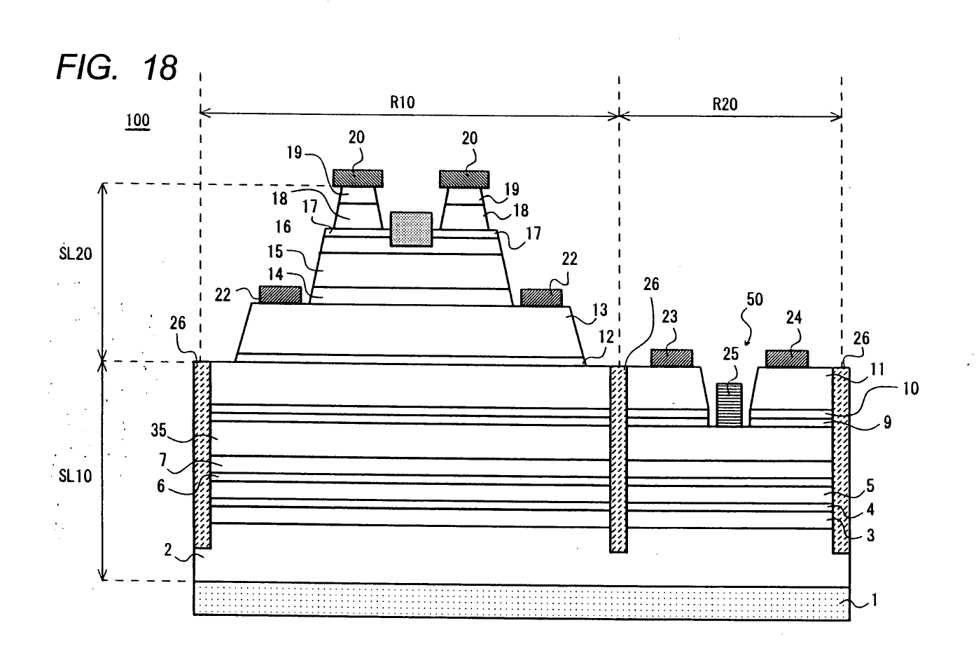

A tenth embodiment is to be described with reference to FIG. 18. FIG. 18 is a cross sectional view showing a schematic cross sectional configuration of a BiFET device. In this embodiment, an n⁻-AlGaAs barrier layer 35 of 25 nm thickness with doping of Si impurity at 3×10¹⁷ cm⁻³ is used instead of the undoped AlGaAs barrier layer 8 shown in the first embodiment. Also in this case, the same effect as that in the first embodiment can be obtained.

As in this embodiment, by doping the AlGaAs barrier layer 35 at a low concentration, lowering of the breakdown voltage can be minimized to reduce the increase in the access resistance caused by the AlGaAs barrier layer 35. As a result, the effect of decreasing the resistance due to doping to the barrier layer is synergistically combined to the effect due to the effect of the GaAs spacer layer 9 and lower ON resistance of FET can be obtained.

### Eleventh Embodiment

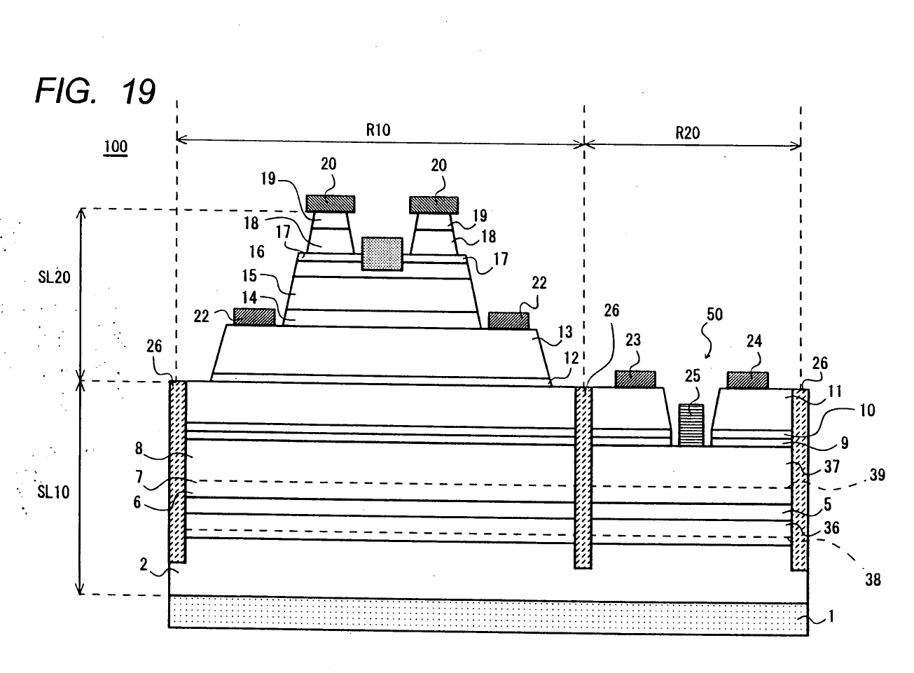

An eleventh embodiment is to be described with reference to FIG. 19. FIG. 19 is a cross sectional view showing a schematic cross sectional configuration of a BiFET device. In the previous embodiments, the n⁺-AlGaAs electron supply layers 3 and 7 are disposed above and below the undoped InGaAs channel layer 5. In this embodiment, instead, an epitaxial structure of adding Si impurity in a sheet form (delta doping structure) is used. Also in this case, the same effect as that in the previous embodiments can be obtained.

As shown in FIG. 19, an Si delta doped layer 38 at a sheet concentration of 1×10¹² cm⁻² is formed in the undoped AlGaAs layer 36 of 6 nm thickness. Further, an Si delta doped layer 39 at a sheet concentration of 3×10¹² cm⁻² is formed in the undoped AlGaAs layer 37 of 30 nm thickness. The Si delta doped layer 38 is formed spaced by 4 nm from the InGaAs channel layer 5. In the same manner, also the Si delta doped layer 39 is formed spaced by 4 nm from the InGaAs channel layer 5. Also in this embodiment, a low ON resistance of FET and a high gate breakdown voltage can be obtained in the same manner as in the previous embodiments.

### Twelfth Embodiment

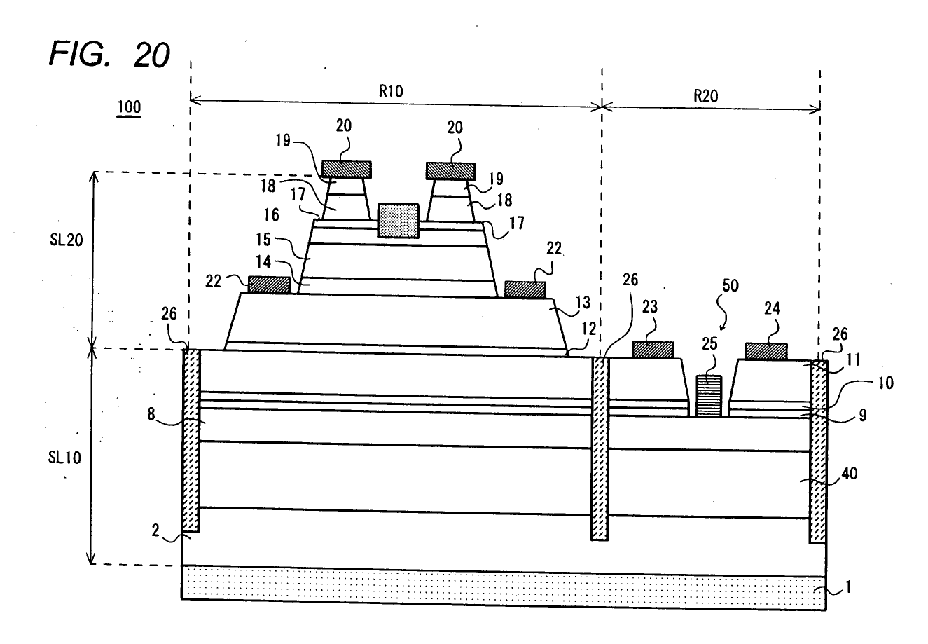

A twelfth embodiment is to be described with reference to FIG. 20. FIG. 20 is a cross sectional view showing a schematic cross sectional configuration of a BiFET device. In the previous embodiments, a high electron mobility transistor (HEMI) structure using the undoped InGaAs layer 5 as a channel is used. In this embodiment, a channel structure different therefrom is used. Also in this embodiment, the same effect as that in the previous embodiments can be obtained.

As shown in FIG. 20, an n-GaAs layer 40 of 100 nm thickness with doping of Si impurity at 3×10¹⁷ cm⁻³ is used as the channel layer. Also in this embodiment, since the GaAs spacer layer 9 is interposed between the InGaP etching stopper layer 10 and the AlGaAs barrier layer 8 in the same manner as in the first embodiment, the access resistance is decreased and low ON resistance of FET can be obtained.

### Thirteenth Embodiment

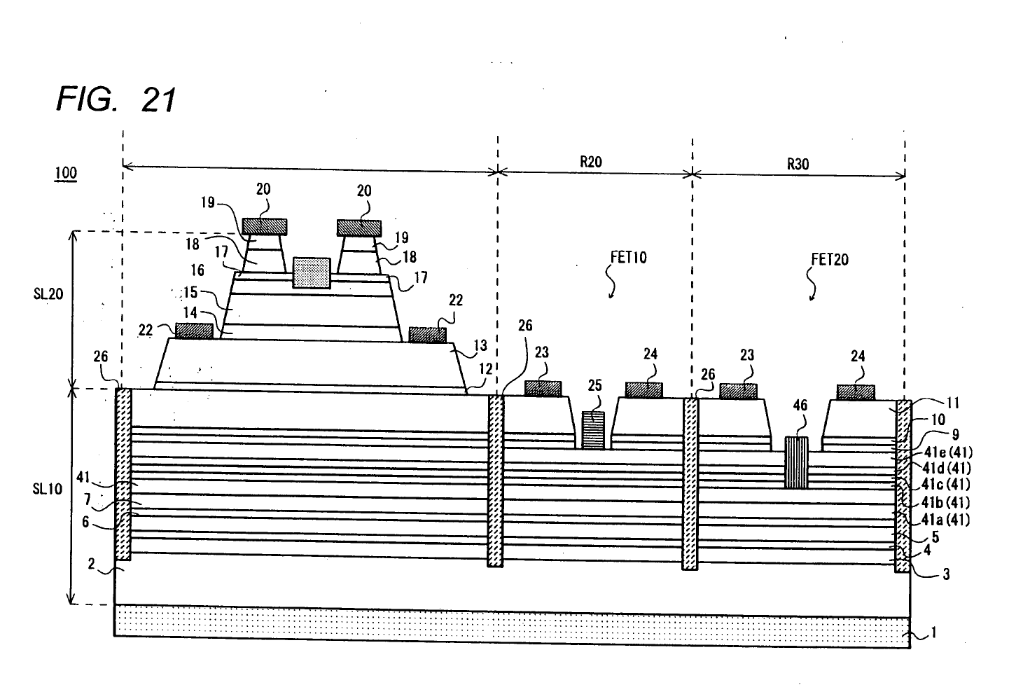

A thirteenth embodiment is to be described with reference to FIG. 21. FIG. 21 is a cross sectional view showing a schematic cross sectional configuration of a BiFET device. In the previous embodiments, a HBT and a FET were formed on one identical substrate. On the contrary, in this embodiment, two FETs are formed on one identical substrate and the threshold voltages of these are made different. Also in this embodiment, the same effect as in the previous embodiments can be obtained.

As shown in FIG. 21, a stack 41 is disposed instead of the undoped AlGaAs barrier layer 8 shown in the first embodiment. The stack 41 comprises an undoped AlGaAs barrier layer 41a of 4 nm thickness, a GaAs spacer layer 41b of 2 nm thickness, an undoped InGaP etching stopper layer 41c of 5 nm thickness, a GaAs spacer layer 41d of 2 nm thickness, and an undoped AlGaAs barrier layer 41e of 15 nm thickness. An enhancement type FET having a positive threshold voltage FET (FET 20) can be formed in doping to a depletion type FET (FET 10) having a negative threshold voltage over identical substrate by disposing a gate electrode 46 in a recess formed by using an InGaP etching stopper layer 41c.

In this embodiment, a GaAs spacer layer 41b is interposed between an InGaP etching stopper layer 41c and an AlGaAs barrier layer 41a and a GaAs spacer layer 41d is interposed between the InGaP etching stopper layer 41c and an AlGaAs barrier layer 41e. This decreases the access resistance in the same manner as in the first embodiment and low ON resistance can be obtained both for the depletion type FET and the enhancement type FET.

### Fourteenth Embodiment

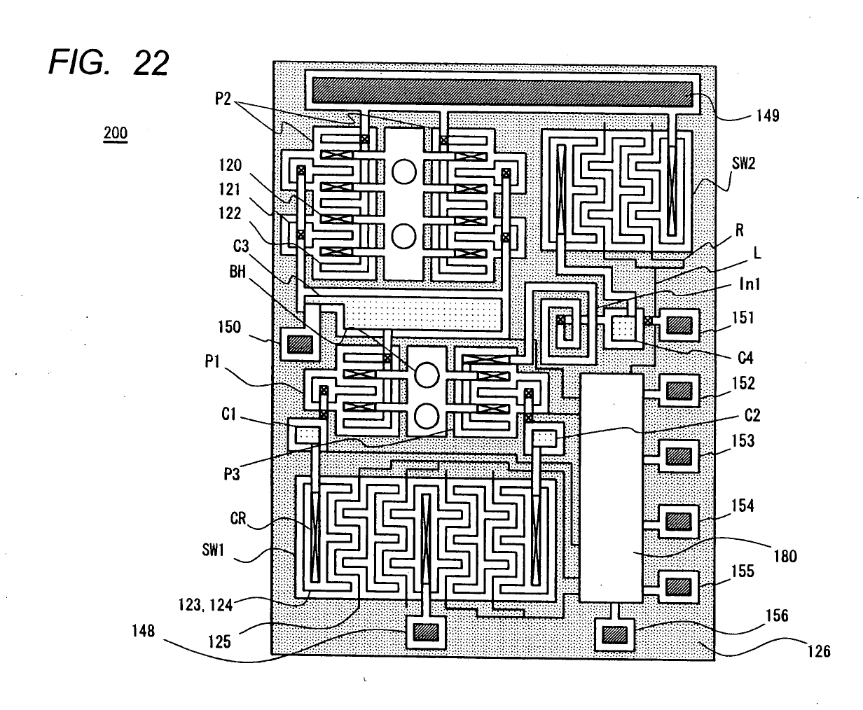

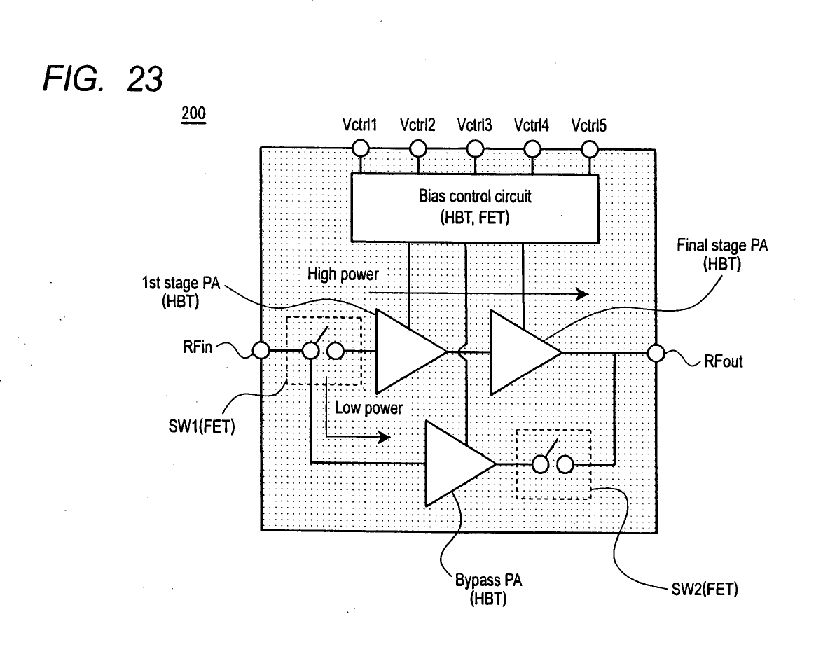

A fourteenth embodiment is to be described with reference to FIGS. 22 and 23. In this embodiment, a power amplifier IC chip comprises a BiFET device shown in one of the previous embodiments. Also in this embodiment, the same effect as that explained for the previous embodiments can be obtained.

FIG. 22 is a schematic view showing a planar configuration of an IC chip 200. FIG. 23 shows an outlined equivalent circuit diagram of the IC chip 200.

As shown in FIG. 22, the IC chip 200 has multiple power amplifiers P1 to P3 comprising the HBT portion in the BiFET process, multiple RF turnover switches SW1 and SW2 comprising a depletion mode FET portion fabricated in the BiFET process, a bias control circuit 180 comprising HBT and FET, multiple capacitors C1 to C4, an inductor In1, multiple gate resistors R, and interconnect lines L. Further, the IC chip 200 has an RF output terminal pad 149, emitter electrodes 120, base electrodes 121, a collector electrode 122, a grounded via hole BH, Vc1 pads 150, a contact portion CR, ohmic electrodes 123, 124, gate electrode 125, an insulating region 126, an RF input terminal pad 148, and control voltage pads 151 to 156.

The emitter electrode 120 corresponds to the emitter electrode 20 shown in the previous embodiments. This is applicable also to the base electrode and the collector electrode. The ohmic electrode 123 corresponds to the electrode 23 shown in the previous embodiments. This is applicable also for the ohmic electrode 124 and the gate electrode 125. One end of a bonding wire is connected to the pad disposed in the IC chip 200 to establish electrical coupling with an external portion (package, module, etc.). The pads 150, 151 are disposed for providing a collector voltage. Pads 152 to 155 are connected to a bias control circuit 180.

As shown in FIG. 23, when a high output power is necessary, the IC chip 200 transmits an RF signal by way of the RF turnover switch SW1 to a power amplifier at the initial stage (1st stage PA:P1), the signal is amplified through the first stage power amplifier—capacitor C3—final stage power amplifier (Final stage PA:P2) and the RF signal amplified to a desired power level is outputted from the RF output terminal pad 149.

When a low output is necessary, for preventing increase in the consumption current upon operation of the final PA (Final stage PA:P2) by using a HBT of a large emitter size, the RF signal is transmitted by way of the RF turnover switch SW1 to a bypass amplifier (Bypass PA:P3), amplified to a desired power level, and is outputted by way of an inductor In1—a capacitor C4—RF turnover switch SW2 from the RF output terminal pad 149.

The RF output power is switched by controlling the output described above in a bias control circuit 180. Since the FET in the BiFET of the first embodiment applied to the IC chip 200 has a low ON resistance, RF signal loss in the change-over switch portion is small. Accordingly, the output power in each of the power amplifiers can be decreased. As a result, this embodiment can provide, a power amplifier IC chip capable of changing the output power while maintaining a high power added efficiency.

### Fifteenth Embodiment

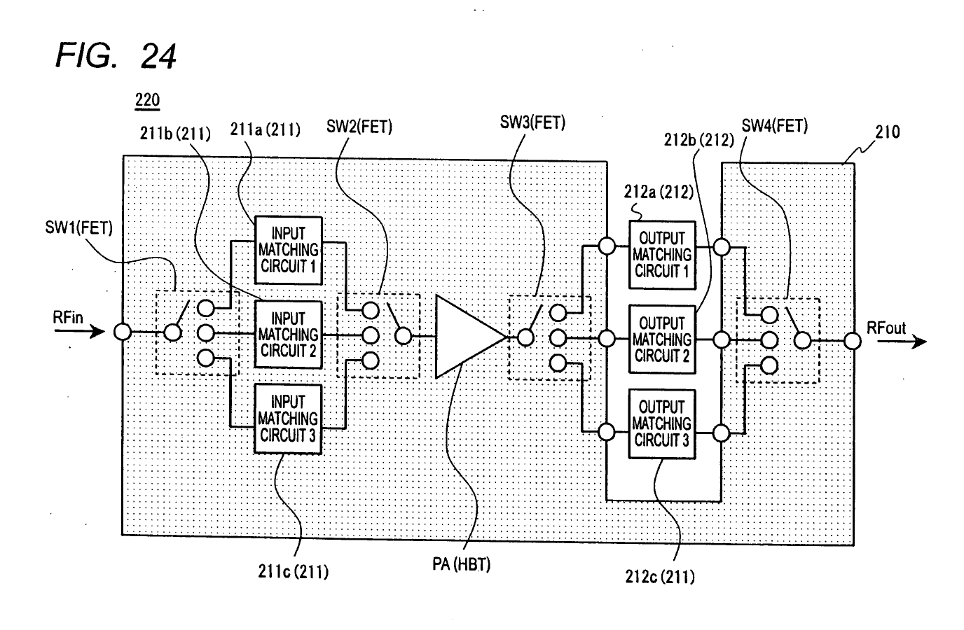

A fifteenth embodiment is to be described with reference to FIG. 24. In this embodiment, a power amplifier IC chip comprises a BiFET device shown in one of the previous embodiments. Also in this case, the same effect as that explained for the previous embodiments can be obtained.

FIG. 24 shows an equivalent circuit diagram of a power amplifier IC in a case of using the BiFET shown in Embodiment 1. As shown in FIG. 24, an IC chip 210 has a power amplifier PA comprising the HBT portion formed in the BiFET process, and multiple input matching circuits 211 (211a to 211c) comprising capacitors and inductors. Output matching circuits 212 (212a to 212c) comprising capacitor and inductor parts are disposed on a module substrate electrically coupled with the IC chip 210.

Three input matching circuits 211a to 211c matched to three frequencies are formed over the IC chip 210. On the other hand, the output matching circuits 212a to 212c preferably comprise parts with less signal loss in the matching circuit portion for passing RF signals amplified by the power amplifier, and they comprise capacitor and inductor components with low internal serial resistance in this embodiment. Then, the input/output matching circuits are turned over by turnover switches SW in the chip.

Since the device 220 having the IC chip 210 and the output matching circuit 212 in combination has a BiFET of lower ON resistance of FET in the same manner as in the first embodiment, loss of RF signals is small in the RF turnover switch portion. Therefore, the output power of the power amplifier can be decreased.

As a result, this embodiment can provide a power amplifier IC chip capable of efficiently amplifying RF signals of different frequencies.

### Reference Example

A reference example is to be explained with reference to FIGS. 25A and 25B. In this reference example, for confirming that the GaAs spacer layer has an effect only to the BiFET epitaxial wafer (refer to FIG. 1: wafer having the stack SL10 and the stack SL201 formed successively over the substrate), a wafer in which only the FET epitaxial layer is grown (refer to FIG. 1: a wafer having only the stack SL10 is formed over a substrate) is provided and an FET is fabricated to evaluate the ON resistance and the access resistance.

In each of the previous embodiments, the bipolar transistor and the field effect transistor are formed on one identical substrate. In the case of the reference example, only the field effect transistor is formed over the substrate. As a result, different from the first embodiment, the stack SL20 is not formed over the stack SL10.

FIG. 25A shows a structure not having a GaAs spacer layer, and having an InGaP etching stopper layer 10 disposed directly on an AlGaAs barrier layer 8. FIG. 25B shows a structure where a GaAs spacer layer 9 is interposed between the AlGaAs barrier layer 8 and the InGaP etching stopper layer 10.

In view of the result of evaluation carried out by the inventors, substantially identical ON resistance of 1.5 Ωmm was obtained for the ON resistance of FETs shown in FIG. 25A and FIG. 25B irrespective of the presence or absence of the GaAs spacer layer. In view of the result, it could be confirmed in a case of forming only the FET over the substrate that no substantial effect of decreasing the ON resistance could be obtained even when the GaAs spacer layer 9 was interposed between the AlGaAs barrier layer 8 and the InGaP etching stopper layer 10.

The present invention is not restricted to the embodiments described above but can be modified optionally within a range not departing from the gist of the invention. For example, other devices than the bipolar transistor, for example, a PIN diode may be fabricated in the stack SL20. Specific materials interposed between the barrier layer and the etching stopper layer may be selected optionally. The spacer layer interposed between the barrier layer and the etching stopper layer may have a multilayer structure.

What is claimed is:

1. A semiconductor device having first and second stacks formed successively over a common substrate,
wherein the first stack that remains after removing the second stack comprises a field effect transistor,
wherein the second stack that is stacked over the first stack comprises a device different from the field effect transistor described above, and
wherein the first stack comprising the field effect transistor contains:
an etching stopper layer that defines a stopping position for a recess formed in the first stack and comprises InGaP;
a lower compound semiconductor layer that is disposed below a gate electrode disposed in the recess and comprises AlGaAs; and
a spacer layer interposed between the etching stopper layer and the lower compound semiconductor layer.

2. The semiconductor device according to claim 1, wherein the spacer layer is interposed between the etching stopper layer and the lower compound semiconductor layer so that phosphorus contained in the etching stopper layer is prevented from thermally diffusing as far as the lower compound semiconductor layer and chemically bonding with constituent elements of the lower compound semiconductor layer.

3. The semiconductor device according to claim 1, wherein the different device formed in the second stack is a bipolar transistor.

4. The semiconductor device according to claim 1, wherein the thickness of the spacer layer is 0.5 nm or more.

5. The semiconductor device according to claim 1, wherein the thickness of the spacer layer is 2 nm or more.

6. The semiconductor device according to claim 1, wherein the spacer layer comprises GaAs.

7. The semiconductor device according to claim 1 having the etching stopper layer as a first etching stopper layer, the device further comprising:
a second etching stopper layer formed over the first etching stopper layer; and
a gate electrode disposed in the recess formed stepwise in accordance with the first and second etching stopper layers.

8. The semiconductor device according to claim 1, wherein an impurity is added to at least one of the etching stopper layer and the spacer layer.

9. The semiconductor device according to claim 1, further comprising:
a compound semiconductor layer formed between the lower compound semiconductor layer and the spacer layer and comprising a material identical with that of the lower compound semiconductor layer,
wherein an impurity is added to the compound semiconductor layer.

10. The semiconductor device according to claim 1, further comprising:
a cap stack formed over the etching stopper layer,
wherein the cap stack contains an intermediate layer having a relatively high resistance between upper and lower compound semiconductor layers.

11. The semiconductor device according to claim 1, wherein an impurity is added to the lower compound semiconductor layer.

12. The semiconductor device according to claim 1, wherein the device includes:
a channel layer comprising an undoped InGaAs layer and a set of electron supply layers disposed above and below the channel layer so as to sandwich the same.

13. The semiconductor device according to claim 1, wherein the device includes:
a channel layer comprising an undoped InGaAs layer; and
a doping structure where an impurity is added sheetwise at a position spaced from the upper surface of the channel layer and where an impurity is added in a sheet form at a position spaced from the lower surface of the channel layer.

14. The semiconductor device according to claim 1, having the field effect transistor as a first field effect transistor, the etching stopper layer as a first etching stopper layer, and the lower compound semiconductor layer as a first compound semiconductor layer, and the spacer layer as a first spacer layer,
wherein the first stack further comprises a second field effect transistor having a threshold voltage different from that of the first field effect transistor, and
wherein the first stack includes:
a second etching stopper layer that defines the stopping position of a recess where the gate electrode of the second field effect transistor is to be disposed and comprises InGaP;
a second lower compound semiconductor layer disposed below the gate electrode of the second field effect transistor and comprising AlGaAs; and
a second spacer layer interposed between the second etching stopper layer and the second lower compound semiconductor layer and preventing phosphorus (P) contained in the second etching stopper layer from thermally diffusing as far as the second lower compound semiconductor layer and chemically bonding with constituent elements of the second lower compound semiconductor layer.

15. The semiconductor device according to claim 1, the different device fabricated in the second stack being a bipolar transistor, the semiconductor device comprising:
an amplifier including the bipolar transistor; and
a switching device including a field effect transistor.

16. A method of manufacturing a semiconductor device comprising:
forming, over a substrate, a first stack, the first stack containing an etching stopper layer that defines the stopping position for a recess and comprises InGaP, a lower compound semiconductor layer that is disposed below a gate electrode disposed in the recess and comprises AlGaAs, and a spacer layer that is interposed between the etching stopper layer and the lower compound semiconductor layer for preventing phosphorus (P) contained in the etching stopper layer from diffusing thermally as far as the lower compound semiconductor layer and chemically bonding with constituent elements of the lower compound semiconductor layer;
epitaxially growing a second stack over the first stack;
partially removing the second stack to expose the upper surface of the first stack;
forming a recess to the upper surface of the first stack till it reaches the stopping position in accordance with the etching stopper layer; and
forming a gate electrode in the recess.
